(19) United States
(12) Patent Application Publication
(10) Pub. No.: US 2026/0327793 A1
(43) Pub. Date: Oct. 22, 2026

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventor: Ryuji YAMAMOTO, Tokyo (JP)

(73) Assignee: KOKUSAI ELECTRIC CORPORATION, Tokyo (JP)

(21) Appl. No.: 19/645,349

(22) Filed: Apr. 13, 2026

(30) Foreign Application Priority Data
Apr. 17, 2025 (JP) 2025-067999

(51) Int. Cl. C23C 16/44; C23C 16/52; H10P 14/60

(52) U.S. Cl. CPC C23C 16/4408; C23C 16/52; H10P 14/6339

(57) ABSTRACT

A technique includes: (a) charging a purge gas into each of a plurality of reservoirs; and (b) sequentially supplying the purge gas from each of the plurality of reservoirs charged with the purge gas into a process chamber a predetermined number of times with an intermittent period therebetween, wherein (b) includes setting the intermittent period to be equal to or less than a charging time of the purge gas being charged into each of the plurality of reservoirs, or setting the intermittent period to be less than the charging time of the purge gas being charged into each of the plurality of reservoirs.

### CROSS-REFERENCE TO RELATED APPLICATION

This application is based upon and claims the benefit of priority from Japanese Patent Application No. 2025-067999, filed on Apr. 17, 2025, the entire contents of which are incorporated herein by reference.

### TECHNICAL FIELD

The present disclosure relates to a processing method, a method of manufacturing a semiconductor device, a processing apparatus, and a recording medium.

### BACKGROUND

In the related art, a processing of purging an interior of a process chamber may be performed in a substrate processing step performed as a process of manufacturing a semiconductor device.

### SUMMARY

The present disclosure provides a technique capable of enhancing a purge effect and a purge efficiency when purging an interior of a process chamber.

According to some embodiments of the present disclosure, there is provided a technique that includes: (a) charging a purge gas into each of a plurality of reservoirs; and (b) sequentially supplying the purge gas from each of the plurality of reservoirs charged with the purge gas into a process chamber a predetermined number of times with an intermittent period therebetween, wherein (b) includes setting the intermittent period to be equal to or less than a charging time of the purge gas being charged into each of the plurality of reservoirs, or setting the intermittent period to be less than the charging time of the purge gas being charged into each of the plurality of reservoirs.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a processing apparatus suitably used in some embodiments of the present disclosure, and illustrates a portion of a process furnace in a vertical cross-sectional view.

FIG. 2 is a schematic configuration diagram of a vertical process furnace of a processing apparatus suitably used in some embodiments of the present disclosure, and illustrates a portion of the process furnace in a cross-sectional view taken along line A-A of FIG. 1.

FIG. 3 is a schematic configuration diagram of a controller of a processing apparatus suitably used in some embodiments of the present disclosure, and illustrates a control system of a controller in a block diagram.

FIG. 4 is a diagram illustrating a processing sequence according to some embodiments of the present disclosure.

FIG. 5 is a diagram illustrating a first modification of a processing sequence according to some embodiments of the present disclosure.

FIG. 6 is a diagram illustrating a second modification of a processing sequence according to some embodiments of the present disclosure.

FIG. 7A is a diagram illustrating one example of a seventh modification according to some embodiments of the present disclosure in which, in step B, an exposure amount of a purge gas to substrates is set to be different between a portion of a plurality of substrates and another portion of the plurality of substrates. FIG. 7B is a diagram illustrating another example of the seventh modification according to some embodiments of the present disclosure in which, in step B, an exposure amount of a purge gas to substrates is set to be different between a portion of a plurality of substrates and another portion of the plurality of substrates. FIG. 7C is a diagram illustrating still another example of the seventh modification according to some embodiment of the present disclosure in which, in step B, an exposure amount of a purge gas to substrates is set to be different between a portion of a plurality of substrates and another of the plurality of substrates.

FIG. 8 is a diagram illustrating a processing sequence according to other embodiments of the present disclosure.

### DETAILED DESCRIPTION

### Embodiments of Present Disclosure

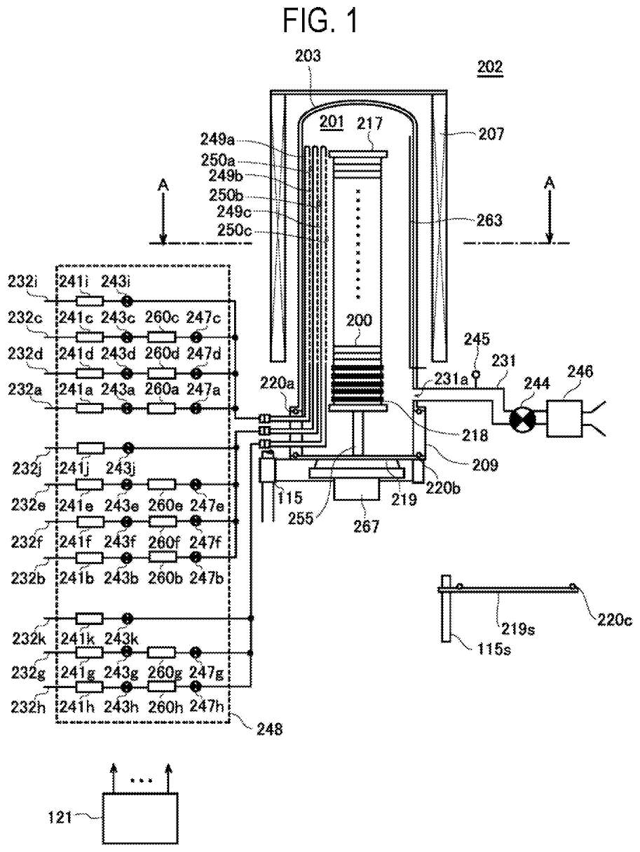

Hereinafter, some embodiments of the present disclosure will be described mainly with reference to FIGS. 1 to 4. In addition, drawings used in the following description are schematic, and dimensional relationships, ratios, and the like of various elements shown in the drawings may not match actual ones. Further, dimensional relationships, ratios, and the like of various elements among plural figures may not match each other.

### (1) Configuration of Processing Apparatus

As illustrated in FIG. 1, a process furnace 202 of a processing apparatus includes a heater 207 that serves as a temperature regulator (heating part). The heater 207 is formed in a cylindrical shape and is supported by a holding plate so as to be vertically installed. The heater also functions as an activator (exciter) configured to activate (excite) gases with heat.

A reaction tube 203 is disposed inside the heater 207 to be concentric with the heater 207. The reaction tube 203 is made of, for example, a heat resistant material such as quartz (SiO₂) or silicon carbide (SiC), and is formed in a cylindrical shape with its upper end closed and its lower end opened. A manifold 209 is disposed to be concentric with the reaction tube 203 under the reaction tube 203. The manifold 209 is constituted by, for example, a metal material such as stainless steel (SUS), and formed in a cylindrical shape with both of its upper and lower ends opened. The upper end of the manifold 209 engages with the lower end of the reaction tube 203 so as to support the reaction tube 203. An O-ring 220a serving as a seal is installed between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating wafers 200 as substrates. Processing on the wafers 200 is performed in the process chamber 201.

Nozzles 249a to 249c as first to third suppliers are installed in the process chamber 201 so as to penetrate a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a, 232b, and 232h are connected to the nozzles 249a to 249c, respectively. The nozzles 249a to 249c are different nozzles, and each of the nozzles 249a and 249c is installed adjacent to the nozzle 249b.

Mass flow controllers (MFCs) 241a, 241b, and 241h, which serve as flow rate controllers (flow rate control parts), valves 243a, 243b, and 243h, which serve as opening/closing valves, tanks 260a, 260b, and 260h, which serve as reservoirs (gas reservoirs), and valves 247a, 247b, and 247h are installed at the gas supply pipes 232a, 232b, and 232c, respectively, sequentially from the upstream side of gas flow. Gas supply pipes 232c, 232d, and 232i are connected, respectively, to the gas supply pipe 232a at the downstream side of the valve 247a. Gas supply pipes 232e, 232f, and 232j are connected, respectively, to the gas supply pipe 232b at the downstream side of the valve 247b. Gas supply pipes 232g and 232k are connected, respectively, to the gas supply pipe 232h at the downstream side of the valve 247h. MFCs 241c to 241g, valves 243c to 243g, tanks 260c to 260g, and valves 247c to 247g are installed at the gas supply pipes 232c to 232g respectively, sequentially from the upstream side of gas flow. MFCs 241i to 241k and valves 243i to 243k are installed at the gas supply pipes 232i to 232k respectively, sequentially from the upstream side of gas flow. The gas supply pipes 232a to 232k are made of, for example, a metallic material such as SUS.

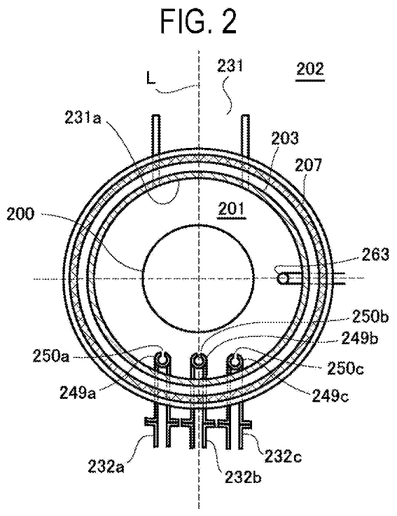

As shown in FIG. 2, each of the nozzles 249a to 249c is installed in an annular space (in plane view) between an inner wall of the reaction tube 203 and the wafers 200 so as to extend upward from a lower side to an upper side of the inner wall of the reaction tube 203, that is, along an arrangement direction of the wafers 200. Specifically, each of the nozzles 249a to 249c is installed in a region horizontally surrounding a wafer arrangement region in which the wafers 200 are arranged at a lateral side of the wafer arrangement region, along the wafer arrangement region. In plane view, the nozzle 249b is disposed so as to face an exhaust port 231a to be described later on a straight line with centers of the wafers 200 in the process chamber 201 interposed therebetween. The nozzles 249a and 249c are arranged with a straight line L passing through the nozzle 249b and the center of the exhaust port 231a interposed therebetween along the inner wall of the reaction tube 203 (an outer peripheral portion of the wafers 200). The straight line L is also a straight line passing through the nozzle 249b and the centers of the wafers 200. That is, it can be said that the nozzle 249c is installed on the side opposite to the nozzle 249a with the straight line L interposed therebetween. The nozzles 249a and 249c are arranged in line symmetry with the straight line L as an axis of symmetry. Gas supply holes 250a to 250c configured to supply a gas are formed on side surfaces of the nozzles 249a to 249c, respectively. Each of the gas supply holes 250a to 250c is opened so as to oppose (face) the exhaust port 231a in plane view, which enables a gas to be supplied toward the wafers 200. A plurality of gas supply holes 250a to 250c are formed from the lower side to the upper side of the reaction tube 203. The nozzles 249a to 249c are also referred to as long nozzles or multi-hole nozzles.

A precursor, which is a first processing agent, is supplied from the gas supply pipe 232a into the process chamber 201 via the MFC 241a, the valve 243a, the tank 260a, the valve 247a, and the nozzle 249a. The precursor is used as a film formation agent.

A reactant, which is a second processing agent, is supplied from the gas supply pipe 232b into the process chamber 201 via the MFC 241b, the valve 243b, the tank 260b, the valve 247b, and the nozzle 249b. The reactant is used as a film formation agent.

Inert gases are supplied from the gas supply pipes 232c to 232h into the process chamber 201 via the MFCs 241c to 241h, the valves 243c to 243h, the tanks 260c to 260h, the valves 247c to 247h, the gas supply pipes 232a to 232c, and the nozzles 249a to 249c, respectively. Inert gases are supplied from the gas supply pipes 232i to 232k into the process chamber 201 via the MFCs 241i to 241k, the valves 243i to 243k, the gas supply pipes 232a to 232c, and the nozzles 249a to 249c, respectively. The inert gases act, for example, as a purge gas, a carrier gas, and a dilution gas.

A first processing agent (precursor) supply system is mainly constituted by the gas supply pipe 232a, the MFC 241a, and the valves 243a and 247a. The tank 260a may also be included in the first processing agent (precursor) supply system. A second processing agent (reactant) supply system is mainly constituted by the gas supply pipe 232b, the MFC 241b, and the valves 243b and 247b. The tank 260b may also be included in the second processing agent (reactant) supply system. An inert gas supply system is mainly constituted by the gas supply pipes 232c to 232k, the MFCs 241c to 241k, and the valves 243c to 243k and 247c to 247h. The tanks 260c to 260h may also be included in the inert gas supply system. Each, a portion, or the entirety of the first processing agent (precursor) supply system and the second processing agent (reactant) supply system is also referred to as a processing agent (film formation agent) supply system. The inert gas supply system is also referred to as a purge gas supply system. Further, the supply systems including the gas supply pipes 232a to 232h, the MFCs 241a to 241h, the valves 243a to 243h and 247a to 247h, and the tanks 260a to 260h are also referred to herein as lines A to H, respectively. Further, the supply systems including the gas supply pipes 232i to 232k, the MFCs 241i to 241k, and the valves 243i to 243k are also referred to as lines I to K, respectively. Further, the tanks 260a to 260h are also referred to as reservoirs A to H, respectively.

One or the entirety of the various supply systems described above, any one or all of the supply systems may be constituted as an integrated supply system 248 in which the valves 243a to 243k and 247a to 247h, the MFCs 241a to 240k, the tanks 260a to 260h, and the like are integrated. The integrated supply system 248 is connected to each of the gas supply pipes 232a to 232k, and is configured such that supply operations of various substances (various gases) into the gas supply pipes 232a to 232k and the tanks 260a to 260h, that is, opening/closing operations of the valves 243a to 243k and 247a to 247h, flow rate regulating operations by the MFCs 241a to 241k, and the like are controlled by a controller 121, which will be described later. The integrated supply system 248 is constituted as an integral or detachable integrated unit, and may be attachable to or detachable from the gas supply pipes 232a to 232k and the like on an integrated unit basis, such that maintenance, replacement, extension and the like of the integrated supply system 248 may be performed on an integrated-unit basis.

The exhaust port 231a configured to exhaust an internal atmosphere of the process chamber 201 is installed below the sidewall of the reaction tube 203. As shown in FIG. 2, in plane view, the exhaust port 231a is installed at a position opposing (facing) the nozzles 249a to 249c (the gas supply holes 250a to 250c) with the wafers 200 interposed therebetween. The exhaust port 231a may be installed from the lower side to the upper side of the sidewall of the reaction tube 203, that is, along the wafer arrangement region. An exhaust pipe 231 is connected to the exhaust port 231a. A vacuum pump 246 as a vacuum exhauster is connected to the exhaust pipe 231 via a pressure sensor 245, which is a pressure detector (a pressure detection part) configured to detect an internal pressure of the process chamber 201, and an auto pressure controller (APC) valve 244, which is a pressure regulator (a pressure regulating part). The APC valve 244 is configured to be capable of performing or stopping a vacuum exhausting operation in the process chamber 201 by opening or closing the valve while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system is mainly constituted by the exhaust pipe 231, the APC valve 244, and the pressure sensor 245. The exhaust system may include the vacuum pump 246.

A seal cap 219, which serves as a furnace opening lid configured to be capable of hermetically sealing a lower end opening of the manifold 209, is installed under the manifold 209. The seal cap 219 is made of, for example, a metal material such as SUS, and is formed in a disc shape. An O-ring 220b, which is a seal making contact with the lower end of the manifold 209, is installed on an upper surface of the seal cap 219. A rotator 267 configured to rotate a boat 217, which will be described later, is installed under the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is constituted as a transporter (transport mechanism) configured to load or unload (transport) the wafers 200 into or out of the process chamber 201 by moving the seal cap 219 up or down.

A shutter 219s, which serves as a furnace opening lid configured to be capable of hermetically sealing a lower end opening of the manifold 209 in a state where the seal cap 219 is lowered and the boat 217 is unloaded from the process chamber 201, is installed under the manifold 209. The shutter 219s is made of, for example, a metal material such as SUS, and is formed in a disc shape. An O-ring 220c, which is a seal making contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed below the boat 217 in multiple stages.

A temperature sensor 263 serving as a temperature detector is installed in the reaction tube 203. Based on temperature information detected by the temperature sensor 263, a state of supplying electric power to the heater 207 is regulated such that a temperature distribution inside the process chamber 201 becomes a desired temperature distribution. The temperature sensor 263 is installed along the inner wall of the reaction tube 203.

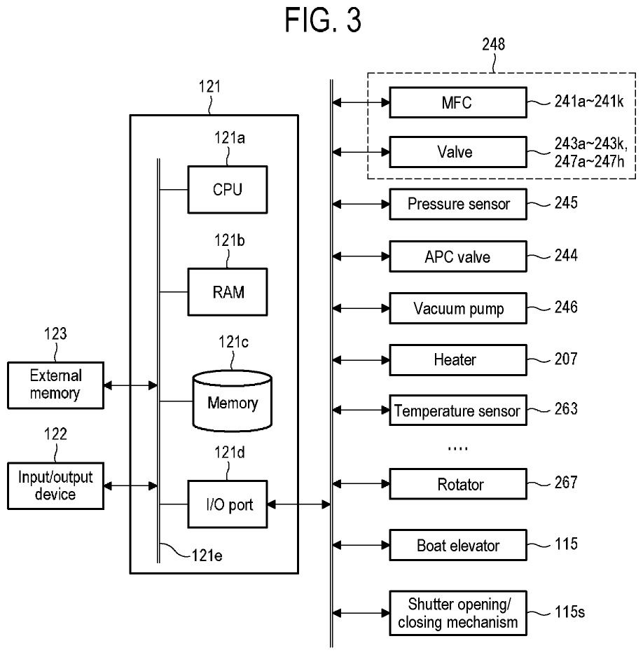

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 including, e.g., a touch panel or the like, is connected to the controller 121. Further, an external memory 123 may be connected to the controller 121. Further, the processing apparatus may be configured to include one controller, or may be configured to include a plurality of controllers. That is, control to perform a processing sequence to be described later may be performed by using one controller, or may be performed by using a plurality of controllers. Further, the plurality of controller may be constituted as a control system in which the plurality of controllers are connected to each other via a wired or wireless communication network, and the entire control system may perform control to perform the processing sequence to be described later. When the term “controller” is used in the present disclosure, it may include one controller, a plurality of controllers, or a control system constituted by a plurality of controllers.

The memory 121c is constituted by, for example, a flash memory, a hard disk drive (HDD), a solid state drive (SSD), or the like. A control program to control operations of a processing apparatus, a process recipe in which sequences and conditions of substrate processing to be described later are written, etc. are readably recorded and stored in the memory 121c. The process recipe functions as a program combined to cause, by the controller 121, the processing apparatus to execute each sequence in the substrate processing, which will be described later, to obtain an expected result. Hereinafter, the process recipe and the control program may be generally and simply referred to as a “program (program product).” Furthermore, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFCs 241a to 241k, the valves 243a to 243k and 247a to 247h, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling flow rate regulating operations of various kinds of substances (gases) by the MFCs 241a to 241h, opening/closing operations of the valves 243a to 243k and 247a to 247h, an opening/closing operation of the APC valve 244, an pressure regulating operation performed by the APC valve 244 based on the pressure sensor 245, actuating and stopping operations of the vacuum pump 246, a temperature regulating operation performed by the heater 207 based on the temperature sensor 263, operations of rotating the boat 217 and adjusting a rotation speed of the boat 217 with the rotator 267, an operation of moving the boat 217 up or down by the boat elevator 115, an opening/closing operation of the shutter 219s by the shutter opening/closing mechanism 115s, and so on, according to contents of the read recipe.

The controller 121 may be constituted by installing, on the computer, the aforementioned program recorded and stored in the external memory 123. Examples of the external memory 123 may include a magnetic disk such as a HDD, an optical disc such as a CD, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Furthermore, the program may be provided to the computer by using communication means or unit such as the Internet or a dedicated line, instead of using the external memory 123.

### (2) Processing Process

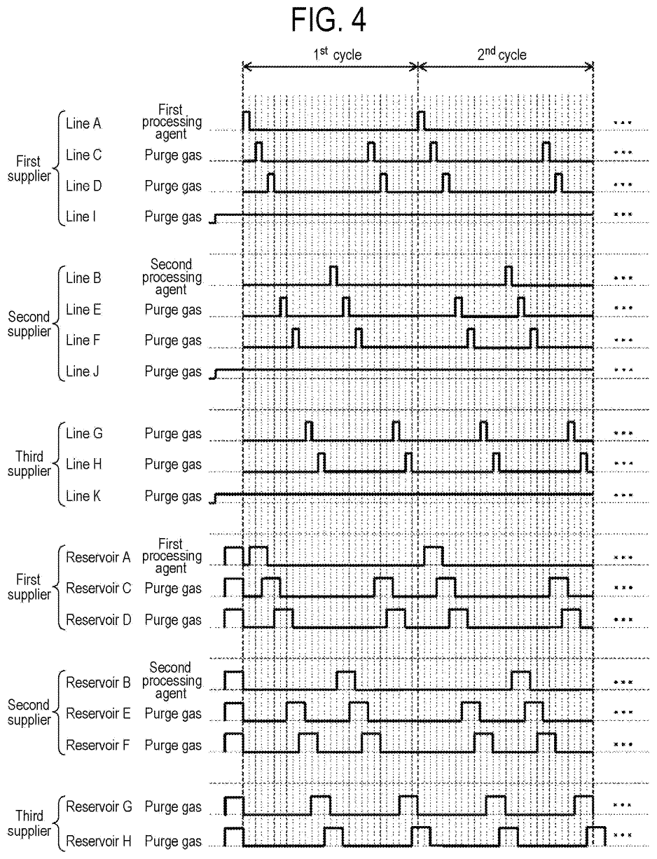

A method of processing a substrate by using the above-described processing apparatus as a process of manufacturing a semiconductor device, that is, an example of a processing sequence to form a film on a surface of the wafer 200 serving as a substrate, will be described mainly with reference to FIG. 4. In the following description, operations of the respective components constituting the processing apparatus are controlled by the controller 121. In addition, the processing apparatus is also referred to as a substrate processing apparatus, a film formation apparatus, or a film formation processing apparatus. Further, the processing method is also referred to as a substrate processing method, a film formation method, or a film formation processing method.

A processing sequence of some embodiments of the present disclosure includes:
(a) step A of charging a purge gas into each of a plurality of reservoirs C to H; and
(b) step B of sequentially supplying the purge gas from each of the plurality of reservoirs C to H charged with the purge gas into the process chamber 201 a predetermined number of times with an intermittent period therebetween, wherein step B includes a step in which the intermittent period is set to be equal to or less than a charging time of the purge gas being charged into the reservoirs C to H, or a step in which the intermittent period is set to be less than the charging time of the purge gas being charged into the reservoirs C to H.

Further, the processing sequence in the embodiments of the present disclosure further includes:
(c) step C of supplying a processing agent to the wafer 200 in the process chamber 201, and
wherein a cycle including steps C and B is performed a predetermined number of times (n times, where n is 1 or an integer of 2 or more).

Specifically, the processing sequence in the embodiments of the present disclosure further includes:
(c1) step C1 of supplying a precursor as a first processing agent to the wafer 200 in the process chamber 201; and
(c2) step C2 of supplying a reactant as a second processing agent to the wafer 200 in the process chamber 201, and
wherein a cycle including steps C1, C2, and B is performed a predetermined number of times (n times, where n is 1 or an integer of 2 or more).

More specifically, in the processing sequence of the embodiments of the present disclosure, a cycle in which steps C1, B, C2, and B are performed in this order a predetermined number of times (n times, where n is 1 or an integer of 2 or more). In addition, step B performed after step C1 and step B performed after step C2 are also referred to as step B1 and step B2, respectively.

When the term “wafer” is used in the present disclosure, it may refer to “a wafer itself” or “a wafer and a stacked body of certain layers or films formed on a surface of the wafer.” When the phrase “a surface of a wafer” is used in the present disclosure, it may refer to “a surface of a wafer itself” or “a surface of a certain layer formed on a wafer.” When the expression “a predetermined layer is formed on a surface of a wafer” is used in the present disclosure, it may mean that “a predetermined layer is formed directly on a surface of a wafer itself” or that “a predetermined layer is formed on a film or the like formed on a wafer.” When the term “substrate” is used in the present disclosure, it may be synonymous with the term “wafer.”

The terms “agent” and “substance” used in the present disclosure include at least one selected from the group of a gaseous substance and a liquefied substance. The liquefied substance includes a misty substance. That is, each of a first processing agent (precursor) and a second processing agent (reactant) may include a gaseous substance, a liquefied substance such as a misty substance, or both of them.

Further, the term “PRG (purge)” as used herein includes supplying a purge gas into a process chamber to clean the interior of the process chamber, discharging and removing substances remaining in the process chamber to the outside of the process chamber, and replacing an internal atmosphere of the process chamber with the purge gas. Further, the term “vacuum (VAC)” includes exhausting (vacuumizing, vacuum-exhausting, or decompressed-exhausting) an interior of a process chamber without supplying a purge gas into a process chamber or while supplying a smaller amount of a purge gas into a process chamber than during PRG. Similarly to PRG, VAC also includes discharging and removing substances remaining in the process chamber to clean the interior of the process chamber.

Further, the terms “flush supply” and “flush flow” as used herein include supplying, in a short burst, a substance (a first processing agent, a second processing agent, or a purge gas) charged in a reservoir into a process chamber under a reduced pressure by utilizing a difference between an internal pressure of the reservoir and an internal pressure of the process chamber. Further, the term “flush purge (FP)” as used herein includes performing the above-described PRG by flush supply of a purge gas.

Further, as will be described later herein, in step B, a plurality of reservoirs are used to intermittently supply a purge gas a plurality of times in short cycles with a shifted timing by flush supply. Specifically, when a cycle in which steps C1, B1, C2, and B2 are performed in this order is carried out a predetermined number of times to form a film on a substrate, in each of steps B1 and B2, a purge gas charged in the plurality of reservoirs C to H is intermittently supplied a plurality of times in short cycles (continuous supply or rapid supply) from each of the plurality of reservoirs C to H. Such FP as used herein, which is performed repeatedly in short cycles, is also referred to as short cycle flush purge (SCFP) or short cycle multi-flush purge (SCMFP).

In addition, FIG. 4 illustrates an example in which FP is performed in six cycles in SCFP in step B1, and FP is performed in six cycles in SCFP in step B2.

Further, a normal purge as used herein, which is performed by supplying a purge gas into a process chamber without charging the purge gas into a reservoir is also referred to as normal purge (NP).

### (Wafer Charge and Boat Loading)

When a plurality of wafers 200 are charged into the boat 217 (wafer charge), the shutter 219s is moved by the shutter opening/closing mechanism 115s, such that the lower end opening of the manifold 209 is opened (shutter opening). Thereafter, as illustrated in FIG. 1, the boat 217 supporting the plurality of wafers 200 is lifted by the boat elevator 115 and is loaded into the process chamber 201 (boat loading). In this state, the seal cap 219 seals the lower end of the manifold 209 via the O-ring 220b. In this way, the wafers 200 are prepared in the process chamber 201.

### (Pressure Regulation and Temperature Regulation)

After the boat loading is completed, the interior of the process chamber 201, that is, a space in which the wafers 200 are present, is vacuum-exhausted (decompressed-exhausted) by the vacuum pump 246, so as to reach a desired pressure (degree of vacuum). At this time, the internal pressure of the process chamber 201 is measured by the pressure sensor 245, and the APC valve 244 is feedback-controlled based on measured pressure information. Further, the wafers 200 in the process chamber 201 are heated to a desired processing temperature by the heater 207. At this time, based on temperature information detected by the temperature sensor 263, a state of supplying electric power to the heater 207 is regulated such that a temperature distribution inside the process chamber 201 becomes a desired temperature distribution. Further, rotation of the wafers 200 is started by the rotator 267. The entirety of the exhaust of the interior of the process chamber 201 and the heating and rotation of the wafers 200 are continuously performed at least until the wafers 200 are completely processed.

### (Step A)

In parallel with these operations, a first processing agent is charged into the tank 260a serving as the reservoir A, a second processing agent is charged into the tank 260b serving as the reservoir B, and a purge gas is charged into the tanks 260c to 260h serving as the reservoirs C to H, respectively.

Specifically, with the valves 247a to 247h closed, the valves 243a to 243h are opened to allow the first processing agent, the second processing agent, and the purge gas to flow through the gas supply pipes 232a to 232h, respectively. These substances are regulated in flow rate by the MFCs 241a to 241h and supplied into the tanks 260a to 260h, and stored in the tanks 260a to 260h, respectively. After the respective substances are stored in the tanks 260a to 260h at respective predetermined amounts and predetermined pressures, the valves 243a to 243h are closed, thereby sealing (confining) the respective substances in a gaseous state in the tanks 260a to 260h. Through a series of these operations, charging of the first processing agent, charging of the second processing agent, and charging of the purge gas into the tanks 260a to 260h are completed, respectively (charging). In addition, a time required from the start to the completion of charging the substance into each of the tanks 260a to 260h is also referred to as a charging time (charge time).

### (Film Formation Processing)

After step A, and the regulation of the internal pressure and internal temperature of the process chamber 201 are completed, the following steps C1, B1, C2, and B2 are performed in order.

### [Step C1]

In this step, the first processing agent (precursor) charged in the reservoir A is supplied to the wafers 200 in the process chamber 201. Here, an example in which a silicon (Si)-containing substance (silane-based gas) is used as the precursor will be described.

Specifically, with the valve 243a closed, the valve 247a is opened. Thereby, the precursor in a high-pressure gaseous state, which is stored in the tank 260a, is supplied in a burst (in a pulsed manner) into the process chamber 201 via the gas supply pipe 232a and the nozzle 249a. At this time, the precursor is supplied to the wafers 200 in a burst under a reduced pressure from the lateral side of the wafers 200, such that the wafers 200 are exposed to the precursor in a burst (flush supply of the precursor and exposure thereto). At this time, the valves 243i to 243k are opened to supply an inert gas into the process chamber 201 via the respective nozzles 249a to 249c. This may prevent intrusion of the precursor into the nozzles 249b and 249c.

By supplying the precursor to the wafers 200 under a processing condition to be described later, a first layer may be formed on a surface of the wafer 200 by adsorption of at least a part of the molecular structure of molecules constituting the precursor. In addition, by flush-supplying the precursor, the precursor may be rapidly diffused throughout the process chamber 201, thereby shortening the exposure time of the wafers 200 to the precursor while uniformly distributing the precursor over the entire wafers 200 within a short time. Further, the timing at which adsorption of the precursor on the wafers 200 starts may be made uniform between the wafers 200. As a result, it is possible to uniformly form the first layer over the entirety of the plurality of wafers 200, that is, over the entire in-plane region of each of the plurality of wafers 200. Further, when recesses such as high-aspect-ratio trenches or holes are formed on the surface of the wafer 200, it is possible to widely distribute the precursor throughout the recesses, thereby uniformly forming the first layer over the entire interiors of the recesses.

After the first layer is formed, the valve 247a is closed to stop the supply of the precursor into the process chamber 201. Thereafter, the precursor is recharged into the tank 260a serving as the reservoir A by the same processing procedure as that described in step A. The recharging of the precursor into the reservoir A is completed by the start timing of the next flush supply of the precursor (step C1 of the next cycle). In addition, FIG. 4 illustrates an example in which the recharging of the precursor into the reservoir A is started immediately after the flush supply of the precursor is completed. However, the present disclosure is not limited to the example of FIG. 4, and the recharging of the precursor into the reservoir A may not be started immediately after the flush supply of the precursor is completed. The recharging of the precursor into the reservoir A may be performed at any timing as long as it may be completed before the next flush supply of the precursor is started.

As the first processing agent (precursor), for example, a substance in which a chloro group (Cl) is bonded to silicon (Si), that is, a chlorosilane-based gas, such as monochlorosilane (SiH₃Cl), dichlorosilane (SiH₂Cl₂), trichlorosilane (SiHCl₃), tetrachlorosilane (SiCl₄), hexachlorodisilane (Si₂Cl₆), or octachlorotrisilane (Si₃Cl₈), may be used. Further, for example, a substance in which hydrogen (H) and an amino group are bonded to Si, that is, an aminosilane-based gas, such as tetrakis(dimethylamino)silane (Si[N(CH₃)₂]₄), tris(dimethylamino)silane (Si[N(CH₃)₂]₃H), bis(diethylamino)silane (Si[N(C₂H₅)₂]₂H₂), bis(tert-butylamino)silane (SiH₂[NH(C₄H₉)]₂), (diisobutylamino)silane (SiH₃[N(C₄H₉)₂]), or (diisopropylamino)silane (SiH₃[N(C₃H₇)₂]), may be used as the precursor. Further, for example, a substance in which an amino group and an alkyl group are bonded to Si, that is, an alkylaminosilane-based gas, such as (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), or (dipropylamino)trimethylsilane ((C₃H₇)₂NSi(CH₃)₃) may be used as the precursor. These substances may also be referred to as substances containing at least one selected from the group of H and an alkyl group, and an amino group. One or more of these substances may be used as the precursor.

As the inert gas, for example, a rare gas such as a nitrogen (N₂) gas, argon (Ar) gas, helium (He) gas, neon (Ne) gas, or xenon (Xe) gas may be used. One or more of these gases may be used as the inert gas. The same applies to steps B1 and B2 to be described later, in which an inert gas is used as the purge gas, and to other steps.

Processing conditions when the first processing agent is flush-supplied in step C1 are exemplified as follows:
Processing temperature: room temperature (25 degrees C) to 700 degrees C, specifically to 650 degrees C;
Processing pressure: 1 to 2,000 Pa, specifically 1 to 1,000 Pa;
Flush supply amount of first processing agent: 0.1 to 2 L, specifically 0.5 to 1 L;
Flush supply time of first processing agent: 1 to 20 seconds, specifically 1 to 10 seconds;
Charging time of the first processing agent being charged into the reservoir: 1 to 20 seconds, specifically 1 to 10 seconds;
Charging pressure of the first processing agent being charged into the reservoir: 10,000 to 80,000 Pa; and
Continuous supply flow rate of inert gas (for each line I, J, or K): 0.1 to 10 slm.

In addition, notation of numerical ranges such as “25 to 700 degrees C” as used herein refers that a lower limit value and an upper limit value are included in that range. Accordingly, for example, “25 to 700 degrees C” refers to “25 degrees C or more and 700 degrees C or less.” The same applies to other numerical ranges. Further, the processing temperature as used herein refers to the temperature of the wafers 200 or the internal temperature of the process chamber 201, and the processing pressure as used herein refers to the internal pressure (absolute pressure) of the process chamber 201. Further, the flush supply amount as used herein refers to the supply amount per flush supply, and the flush supply time as used herein refers to the supply time per flush supply. Further, the charging time as used herein refers to a time required from the start to the completion of charging of a substance into the reservoir, and the charging pressure as used herein refers to the internal pressure of the reservoir when a substance is charged into the reservoir. Further, the continuous supply flow rate of inert gas (for each line I, J, or K) refers to a flow rate of each inert gas supplied from each line I, J, or K. [Step B1]

After step C1 is completed, the purge gas is sequentially supplied into the process chamber 201 from each of the reservoirs C to H charged with the purge gas a predetermined number of times (n₁ times, where n₁ is an integer of 2 or more) with an intermittent period therebetween, thereby performing SCFP. In the embodiments of the present disclosure, an example in which n₁ is set to 6, that is, an example in which FP is performed in six cycles in SCFP will be described by way of example.

Specifically, with the valve 243c closed, the valve 247c is opened. Thereby, the high-pressure purge gas stored in the tank 260c is supplied in a burst (in a pulsed manner) into the process chamber 201 under a reduced pressure through the gas supply pipe 232c and the nozzle 249a (flush supply of the purge gas by the line C). After the flush supply of the purge gas by the line C is performed, the valve 247c is closed. Thereafter, the flush supply of the purge gas by the lines D to H is sequentially performed with a shifted timing by the same processing procedure. That is, in this step, with the valves 243c to 243h closed respectively, the valves 247c to 247h are sequentially opened, respectively, with a shifted timing. After the flush supply of the purge gas by each line is completed, the valves 247c to 247h are sequentially closed. Thereby, FP by the lines C to H may be sequentially performed with a shifted timing (first SCFP). Each time the flush supply is performed once, at least a part of the first processing agent and reaction by-products remaining in the process chamber 201 is pushed (pressure-fed) by the high-pressure (high-flow-rate) purge gas and discharged from the exhaust port 231a. At this time, at least a part of the atmosphere in the process chamber 201 is replaced with the purge gas.

Here, in step B1, a series of flush supplies by these lines C to H is sequentially performed with a predetermined intermittent period therebetween. Further, each intermittent period is set to be equal to or less than the charging time of the purge gas into the tanks 260c to 260h, or each intermittent period is set to be less than the charging time of the purge gas into the tanks 260c to 260h. In addition, VAC in the process chamber 201 may be performed during the intermittent period. The purge gas charged in the plurality of reservoirs C to H is intermittently supplied into the process chamber 201 a plurality of times in short cycles (continuous supply or rapid supply). FP in short cycles, that is, SCFP, is performed in this manner, and by this SCFP, the purge effect and the purge efficiency in the process chamber 201 may be enhanced, respectively. As a result, it is possible to efficiently discharge the first processing agent and reaction by-products remaining in the process chamber 201 from the inside of the process chamber 201. In a case where recesses are formed on the surface of the wafer 200, it is possible to efficiently discharge the first processing agent and reaction by-products from inside of the recess.

In addition, in SCFP in step B1, FP may be first performed via the nozzle 249a by the lines C and D, and then FP may be performed via the nozzle 249b by the lines E and F or via the nozzle 249c by the lines G and H. FIG. 4 illustrates an example in which, in SCFP in step B1, FP is performed by using the lines C to H in this order, that is, via the nozzles 249a to 249c in this order. Thereby, initially, the first processing agent remaining in the nozzle 249a after step C1 is completed may be removed by being pushed out into the process chamber 201, thereby enabling SCFP to be efficiently performed. In a case where FP is first performed by using the lines E and F or the lines G and H, and then FP is performed by using the lines C and D, the first processing agent remaining in the nozzle 249a may be pushed out into the process chamber 201 from which the first processing agent was removed by FP, which may reduce the purge efficiency.

In SCFP, after the flush supply of the purge gas by the lines C to H is sequentially performed and the valves 247c to 247h are sequentially closed, the purge gas is recharged into the tanks 260c to 260h at respective predetermined timings by the same processing procedure as that described in step A. The recharging of the purge gas into the tanks 260c to 260h is completed by the start timing of the next flush supply of the purge gas, that is, by the completion timing of step C2 (flush supply of the second processing agent) of the present cycle. FIG. 4 illustrates an example in which the recharging of the purge gas into the tanks 260c to 260h is sequentially started immediately after the flush supply is performed.

Processing conditions when the purge gas is flush-supplied in step B1 are exemplified as follows:
Processing pressure: 1 to 1,000 Pa, specifically 1 to 500 Pa;
Flush supply amount of purge gas: 0.05 to 2 L, specifically 0.1 to 1 L;
Flush supply time of purge gas: 1 to 20 seconds, specifically 1 to 10 seconds;
Number of times of purge gas flush supplies: 2 to 100 times, specifically 2 to 50 times
Intermittent period between purge gas flush supplies: 1 to 10 seconds, specifically 1 to 5 seconds;
Charging time of the purge gas being charged into the reservoir: 1 to 20 seconds, specifically 1 to 10 seconds; and
Charging pressure of the purge gas being charged into the reservoir: 10,000 to 80,000 Pa. Other processing conditions may be the same as those when the first processing agent is flush-supplied in step C1.

### [Step C2]

After step B1 is completed, the second processing agent (reactant) charged in the reservoir B is supplied to the wafers 200 in the process chamber 201. Here, an example in which a nitriding agent (nitriding gas) is used as the reactant will be described.

Specifically, with the valve 243b closed, the valve 247b is opened. Thereby, the reactant in a high-pressure gaseous state, which is stored in the tank 260b, is supplied in a burst (in a pulsed manner) into the process chamber 201 via the gas supply pipe 232b and the nozzle 249b. At this time, the reactant is supplied to the wafers 200 in a burst under a reduced pressure from the lateral side of the wafers 200, such that the wafers 200 are exposed to the reactant in a burst (flush supply of the reactant and exposure thereto). At this time, the valves 243i to 243k are opened to supply an inert gas into the process chamber 201 via the respective nozzles 249a to 249c. This may prevent intrusion of the reactant into the nozzles 249a and 249c.

By supplying the reactant to the wafers 200 under a processing condition to be described later, at least a part of the first layer formed on the surface of the wafer 200 in step C1 may be modified (nitrided). Thereby, a second layer in which at least a part of the first layer is modified (nitrided) may be formed on the surface of the wafer 200. Further, by flush-supplying the reactant, the reactant may be rapidly diffused throughout the process chamber 201, thereby shortening the exposure time of the wafers 200 to the reactant while uniformly distributing the reactant over the entire wafers 200 within a short time. Further, the timing at which modification (nitridation) of the first layer by the reactant starts may be aligned between the wafers 200. As a result, it is possible to uniformly form the second layer over the entirety of the plurality of wafers 200, that is, over the entire in-plane region of each of the plurality of wafers 200. Further, when recesses are formed on the surface of the wafer 200, it is possible to widely distribute the reactant throughout the recesses, thereby uniformly forming the second layer over the entire interiors of the recesses.

After the second layer is formed, the valve 247b is closed to stop the supply of the reactant into the process chamber 201. Thereafter, the reactant is recharged into the tank 260b serving as the reservoir B by the same processing procedure as that described in step A. The recharging of the reactant into the reservoir B is completed by the start timing of the next flush supply of the reactant (step C2 of the next cycle). In addition, FIG. 4 illustrates an example in which the recharging of the reactant into the reservoir B is started immediately after the flush supply of the reactant is completed. However, the present disclosure is not limited to the example of FIG. 4, and the recharging of the reactant into the reservoir B may not be started immediately after the flush supply of the reactant is completed. The recharging of the reactant into the reservoir B may be performed at any timing as long as it may be completed before the next flush supply of the reactant is started.

The second processing agent (reactant) may be a nitriding agent, for example, a nitrogen-and hydrogen-containing substance such as ammonia (NH₃), diazen (N₂H₂), hydrazine (N₂H₄), or N₃H₈, that is, a hydrogen-nitride-based gas.

Processing conditions when the second processing agent is flush-supplied in step C2 are exemplified as follows:
Processing pressure: 1 to 3,000 Pa, specifically 1 to 2,000 Pa;
Flush supply amount of second processing agent: 0.1 to 2 L, specifically 0.5 to 1 L;
Flush supply time of second processing agent: 1 to 20 seconds, specifically 1 to 10 seconds;
Charging time of the second processing agent being charged into the reservoir: 1 to 20 seconds, specifically 1 to 10 seconds;
Charging pressure of the second processing agent being charged into the reservoir: 10,000 to 80,000 Pa. Other processing conditions may be the same as those when the first processing agent is flush-supplied in step C1.

### [Step B2]

After step C2 is completed, the purge gas is sequentially supplied into the process chamber 201 from each of the reservoirs C to H charged with the purge gas a predetermined number of times (n₂ times, where n₂ is an integer of 2 or more) with an intermittent period therebetween in accordance with approximately the same processing procedure as that in step B1 described above, thereby performing SCFP (second SCFP). In the embodiments of the present disclosure, an example in which n₂ is set to 6, that is, an example in which FP is performed in six cycles in SCFP will be described by way of example.

Here, in step B2, a series of flush supplies by these lines C to H is sequentially performed with a predetermined intermittent period therebetween. Further, each intermittent period is set to be equal to or less than the charging time of the purge gas into the tanks 260c to 260h, or each intermittent period is set to be less than the charging time of the purge gas into the tanks 260c to 260h. In addition, VAC in the process chamber 201 may be performed during the intermittent period. The purge gas charged in the plurality of reservoirs C to H is intermittently supplied into the process chamber 201 a plurality of times in short cycles (continuous supply or rapid supply). FP in short cycles, that is, SCFP, is performed in this manner, and by this SCFP, the purge effect and purge efficiency in the process chamber 201 may be enhanced, respectively. As a result, it is possible to efficiently discharge the second processing agent and reaction by-products remaining in the process chamber 201 from the process chamber 201. When recesses are formed on the surface of the wafer 200, it is possible to efficiently discharge the second processing agent and reaction by-products from insides of the recesses.

In addition, in SCFP in step B2, FP may be first performed via the nozzle 249b by the lines E and F, and then FP may be performed via the nozzle 249a by the lines C and D or via the nozzle 249c by the lines G and H. FIG. 4 illustrates an example in which, in SCFP in step B2, FP is performed by using the lines E, F, C, D, G, and H in this order, that is, via the nozzles 249b, 249a, and 249c in this order. Thereby, initially, the second processing agent remaining in the nozzle 249b after step C2 is completed may be removed by being pushed out into the process chamber 201, thereby enabling SCFP to be efficiently performed. In a case where FP is first performed by using the lines C and D or the lines G and H, and then FP is performed by using the lines E and F, the second processing agent remaining in the nozzle 249b may be pushed out into the process chamber 201 from which the second processing agent was removed by FP, which may reduce the purge efficiency.

In SCFP, after the flush supply of the purge gas by the lines C to H is sequentially performed and the valves 247c to 247h are sequentially closed, the purge gas is recharged into the tanks 260c to 260h at respective predetermined timings by the same processing procedure as that described in step A. The recharging of the purge gas into the tanks 260c to 260h is completed by the start timing of the next flush supply of the purge gas, that is, by the completion timing of step C1 (flush supply of the first processing agent) of the next cycle. FIG. 4 illustrates an example in which the recharging of the purge gas into the tanks 260c to 260h is sequentially started immediately after the flush supply is performed.

Processing conditions when the purge gas is flush-supplied in step B2 may be the same as the processing conditions when the purge gas is flush-supplied in step B1.

### [Performing Predetermined Number of Times]

By performing a cycle including the above-described steps C1, B1, C2, and B2 a predetermined number of times (n₃ times, where n₃ is 1 or an integer of 2 or more), it is possible to form a film with a desired thickness on the wafer 200. When the above-described precursor and reactant are used as the first processing agent and the second processing agent, respectively, it is possible to form, as the film on the wafer 200, for example, a silicon nitride film (SiN film). The above-described cycle may be performed a plurality of times. That is, the thickness of the second layer formed per cycle may be set to be smaller than a desired film thickness, and that the above-described cycle may be performed a plurality of times until the thickness of the film formed by stacking the second layers reaches the desired thickness.

In addition, in the above-described embodiments, the example is described in which FP is performed in six cycles in SCFP in each of steps B1 and B2, but the present disclosure is not limited thereto. That is, in SCFP in each of steps B1 and B2, FP may be performed in two or more cycles, and for example, may be performed in seven or more cycles.

For example, in step B1, the above-described SCFP, which uses the lines C to H in this order, may be performed twice to perform a total of twelve cycles for SCFP, and in step B2, the above-described SCFP, which uses the lines E, F, C, D, G, and H in this order, may be performed twice to perform a total of twelve cycles for SCFP. In this case as well, similarly to the above-described embodiments, after the flush supply of the purge gas from one reservoir is completed, the flush supply of the purge gas from another reservoir may be performed in parallel with the charging of the purge gas into the one reservoir. By appropriately adjusting the timing of the flush supply of the purge gas and the charging of the purge gas into the reservoir in this manner, it is possible to repeatedly perform intermittent supplies of the purge gas by flush supply in short cycles (continuous supply or rapid supply) any number of times.

In addition, from the viewpoint of productivity, in each of steps B1 and B2, the number of cycles for SCFP may be 100 cycles or less, specifically 50 cycles or less, and more specifically 30 cycles or less. In addition, from the viewpoint of purge effect, in each of steps B1 and B2, the number of cycles for SCFP may be 2 cycles or more, specifically 5 cycles or more, and more specifically 10 cycles or more.

### (After-Purge and Returning to Atmospheric Pressure)

After the film formation processing is completed, an inert gas serving as the purge gas is supplied into the process chamber 201 from the respective nozzles 249a to 249c, and is exhausted from the exhaust port 231a. Thereby, the interior of the process chamber 201 is purged, and any gases and reaction by-products remaining in the process chamber 201 are removed from the process chamber 201 (after-purge). Thereafter, the atmosphere in the process chamber 201 is replaced with the inert gas (inert gas replacement), and the internal pressure of the process chamber 201 is returned to a normal pressure (returning to atmospheric pressure).

### (Boat Unloading and Wafer Discharge)

Thereafter, the seal cap 219 is lowered by the boat elevator 115 to open the lower end of the manifold 209. Then, the processed wafer 200 is unloaded (boat-unloaded) from the lower end of the manifold 209 to the outside of the reaction tube 203 while being supported on the boat 217. After boat unloading, the shutter 219s is moved, and the lower end opening of the manifold 209 is sealed by the shutter 219s via the O-ring 220c (shutter closing). The processed wafer 200 is unloaded to the outside of the reaction tube 203, and is then discharged from the boat 217 (wafer discharging).

### (3) Effects of Present Embodiment

According to the embodiments of the present disclosure, one or more of effects described below are obtained.

(a) Step A of charging a purge gas into each of a plurality of reservoirs, and step B of sequentially supplying the purge gas from each of the plurality of reservoirs charged with the purge gas into a process chamber a predetermined number of times with an intermittent period therebetween are performed, and step B includes a step of setting the intermittent period to be equal to or less than a charging time of the purge gas being charged into the reservoir, or a step of setting the intermittent period to be less than the charging time of the purge gas being charged into the reservoir. Thereby, it is possible to intermittently supply the purge gas a plurality of times in short cycles (continuous supply or rapid supply) with a shifted timing by flush supply from each of the plurality of reservoirs, thereby making it possible to enhance both the purge effect and the purge efficiency when purging the interior of the process chamber.

That is, SCFP is configured to include a period during which recharging of the purge gas into at least one reservoir among the plurality of reservoirs and flush supply of the purge gas from another reservoir different therefrom are performed in parallel. Further, SCFP is configured to include a period during which recharging of the purge gas into at least one reservoir among the plurality of reservoirs and recharging of the purge gas into another reservoir different therefrom are performed in parallel. Thereby, the intermittent period of the flush supply of the purge gas in SCFP may be set to be equal to or less than the charging time of the purge gas being charged into the reservoir, or the intermittent period of the flush supply of the purge gas in SCFP may be set to be less than the charging time of the purge gas being charged into the reservoir, and it is possible to intermittently supply the purge gas a plurality of times in short cycles with a shifted timing by flush supply (continuous supply or rapid supply).

Then, thereby, it is possible to repeatedly and intensively apply a strong impact due to the high-pressure (high-flow-rate) purge gas to a purge target location at short intervals, thereby enhancing both the purge effect and the purge efficiency, respectively. In addition, this action may be effectively obtained by setting the intermittent period of the flush supply of the purge gas in SCFP to be equal to or less than the charging time of the purge gas being charged into the reservoir. In addition, it is possible to more effectively obtain this action by setting the intermittent period of the flush supply of the purge gas in SCFP to be less than the charging time of the purge gas being charged into the reservoir. That is, as the intermittent period of the flush supply of the purge gas in SCFP becomes shorter, a stronger impact may be applied to the purge target location at shorter intervals, making it possible to realize this action more effectively.

In addition, when one reservoir is installed, the intermittent period of the flush supply of the purge gas may not be set to be shorter than the charging time of the purge gas being charged into the reservoir. This is because, when one reservoir is installed, the next flush supply of the purge gas may not be performed until the charging of the purge gas into the reservoir is completed.

(b) A cycle including step C of supplying a processing agent to a substrate in the process chamber and the above-described step B is performed a predetermined number of times. Specifically, a cycle including the above-described steps C1, B1, C2, and B2 is performed a predetermined number of times. Thereby, both the purge effect and the purge efficiency may be enhanced when purging and removing, e.g., residual components of the first and second processing agents and reaction by-products in the process chamber and on the surface of the substrate. As a result, it is possible to shorten the time to sufficiently remove the residual components of the first and second processing agents and reaction by-products from inside the process chamber and the surface of the substrate, for example, from insides of recesses formed in the surface of the substrate, thereby improving productivity.

(c) In step B (steps B1 and B2), SCFP may be performed in the process chamber and in each line and in each nozzle. Thereby, both the purge effect and the purge efficiency may be enhanced, respectively, when purging and removing residual components of the first and second processing agents in each line and in each nozzle. Further, even in a case where, e.g., the first and second processing agents and reaction by-products enter each line and each nozzle, both the purge effect and the purge efficiency may be enhanced when purging and removing them. As a result, it is possible to shorten the time to sufficiently remove the first and second processing agents and reaction by-products from insides of each line and each nozzle, thereby improving productivity. (d) The above-described effects may be similarly obtained even in a case where predetermined substances are arbitrarily selected and used from among the above-described various first processing agents, various second processing agents, and various purge gases.

### (4) Modifications

The processing sequence in the embodiments of the present disclosure may be changed as in the following modifications. These modifications may be combined arbitrarily. Unless otherwise specified, the processing procedure and processing condition in each step of each modification may be the same as those in each step of the above-described processing sequence.

### (First Modification)

There are cases in which one of the first processing agent and the second processing agent is more likely to remain than the other. In such a case, at least one selected from the group of the number of times of supplying the purge gas, the supply cycle of the purge gas, the total supply amount of the purge gas, the maximum supply flow rate of the purge gas, the charging pressure of the purge gas being charged into the reservoir for supply, the charging time of the purge gas being charged into the reservoir for supply, the volume of the reservoir charged with the purge gas for supply, the charging amount of the purge gas being charged into the reservoir for supply, the supply amount of the purge gas for each supply, and the maximum pressure change amount in the process chamber may be regulated to be different between step B1 and step B2.

For example, the first processing agent may be more likely to remain in recesses on the surface of the substrate than the second processing agent. In this case, for example, at least one of the following regulations is performed.

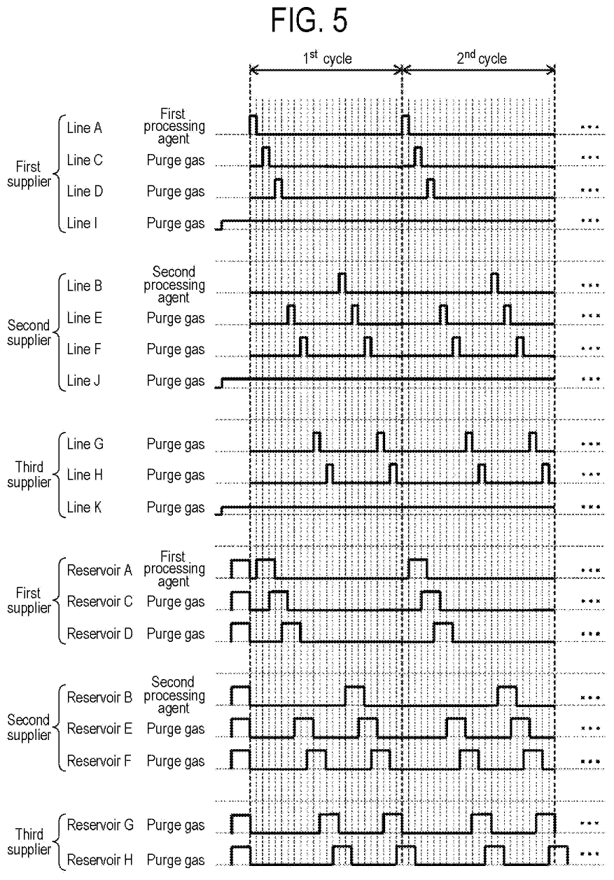

For example, as illustrated in FIG. 5, the number of times of supplying the purge gas in step B1 is set to be greater than the number of times of supplying the purge gas in step B2. FIG. 5 illustrates an example in which the number of times of supplying the purge gas in step B1 is six times and the number of times of supplying the purge gas in step B2 is four times. For example, the number of times of supplying the purge gas in step B 1 may be set to 10 to 20 times, and the number of times of supplying the purge gas in step B2 may be set to 2 to 9 times.

Further, for example, the supply cycle of the purge gas in step B1 is set to be shorter than the supply cycle of the purge gas in step B2. For example, the supply cycle of the purge gas in step B1 may be set to 1 to 4 seconds, and the supply cycle of the purge gas in step B2 may be set to 5 to 10 seconds.

Further, for example, the total supply amount of the purge gas in step B1 is set to be greater than the total supply amount of the purge gas in step B2. For example, the total supply amount of the purge gas in step B1 may be set to 5 to 20 L, and the total supply amount of the purge gas in step B2 may be set to 1 to 4 L.

Further, for example, the maximum supply flow rate of the purge gas in step B1 is set to be greater than the maximum supply flow rate of the purge gas in step B2. For example, the maximum supply flow rate of the purge gas in step B1 may be set to 20 to 50 slm, and the maximum supply flow rate of the purge gas in step B2 may be set to 1 to 19 slm.

Further, for example, the charging pressure of the purge gas being charged into the reservoir for supply in step B1 is set to be higher than the charging pressure of the purge gas being charged into the reservoir for supply in step B2. For example, the charging pressure of the purge gas being charged into the reservoir for supply in step B1 is set to 20,000 to 80,000 Pa, and the charging pressure of the purge gas being charged into the reservoir for supply in step B2 is set to 10,000 to 19,000 Pa. Further, for example, the charging time of the purge gas being charged into the reservoir for supply in step B1 is set to be longer than the charging time of the purge gas being charged into the reservoir for supply in step B2. For example, the charging time of the purge gas being charged into the reservoir for supply in step B1 is set to 6 to 10 seconds, and the charging time of the purge gas being charged into the reservoir for supply in step B2 is set to 1 to 5 seconds. Further, for example, the volume of the reservoir charged with the purge gas for supply in step B1 is set to be greater than the volume of the reservoir charged with the purge gas for supply in step B2. For example, the volume of the reservoir charged with the purge gas for supply in step B1 is set to 3 to 4 L, and the volume of the reservoir charged with the purge gas for supply in step B2 is set to 1 to 2 L. In such an example, the charging amount of the purge gas being charged into the reservoir for supply in step B1 may be set to be greater than the charging amount of the purge gas being charged into the reservoir for supply in step B2. For example, the charging amount of the purge gas being charged into the reservoir for supply in step B1 may be set to 2 to 3 L, and the charging amount of the purge gas being charged into the reservoir for supply in step B2 may be set to 1 to 1.5 L. That is, in such an example, the supply amount of the purge gas for each supply in step B1 may be set to be greater than the supply amount of the purge gas for each supply in step B2. In addition, in such an example and the example of FIG. 5, it is possible to make the total supply amount of the purge gas in step B1 greater than the total supply amount of the purge gas in step B2.

Further, for example, the maximum pressure change amount in the process chamber in step B1 is set to be greater than the maximum pressure change amount in the process chamber in step B2. For example, the maximum pressure change amount in the process chamber in step B1 is set to 1,000 to 3,000 Pa, and the maximum pressure change amount in the process chamber in step B2 is set to 500 to 900 Pa.

In this modification as well, effects similar to those of the above-described embodiments are obtained. Further, according to this modification, by performing at least one of these regulations, the purge effect in step B1 may be higher than the purge effect in step B2. Thereby, even in a case where the first processing agent is more likely to remain in recesses on the surface of the substrate than the second processing agent, it is possible to sufficiently remove residual components of both the first processing agent and the second processing agent from the surface of the substrate.

### (Second Modification)

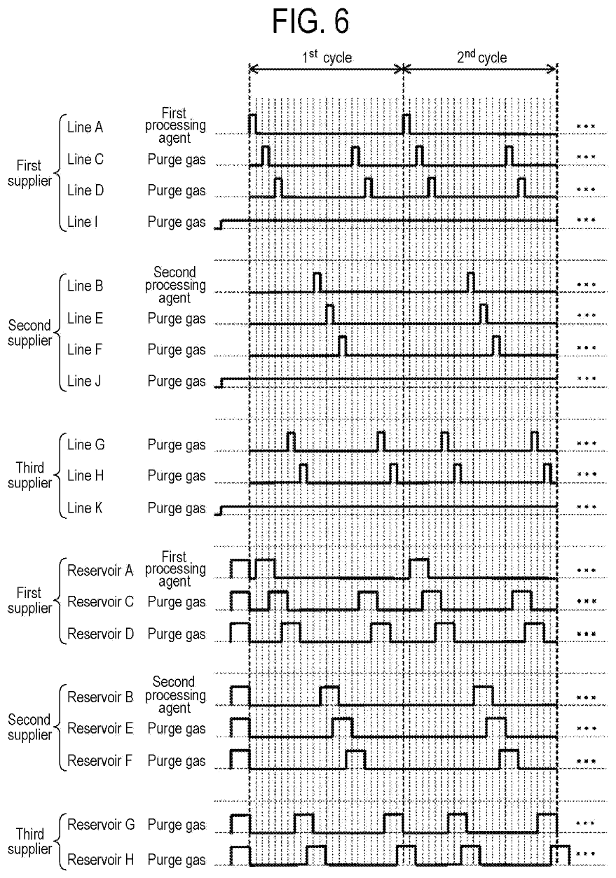

For example, the second processing agent may be more likely to remain in recesses on the surface of the substrate than the first processing agent. In this case, for example, various regulations in the above-described first modification may be performed by replacing step B1 with step B2 and replacing step B2 with step B1. One example of these various regulations is illustrated in FIG. 6. FIG. 6 illustrates an example in which the number of times the purge gas is supplied in step B2 is set to be greater than the number of times the purge gas is supplied in step B1. Specifically, FIG. 6 illustrates an example in which the number of times the purge gas is supplied in step B1 is four times and the number of times the purge gas is supplied in step B2 is six times. For example, the number of times the purge gas is supplied in step B1 may be set to 2 to 9 times, and the number of times the purge gas is supplied in step B2 may be set to 10 to 20 times. In addition, in the example of FIG. 6, it is also possible to make the total supply amount of the purge gas in step B2 greater than the total supply amount of the purge gas in step B1.

In this modification as well, effects similar to those of the above-described embodiments are obtained. Further, according to this modification, by performing at least one of these regulations, the purge effect in step B2 may be higher than the purge effect in step B1. Thereby, even in a case where the second processing agent is more likely to remain in recesses on the surface of the substrate than the first processing agent, it is possible to sufficiently remove residual components of both the first processing agent and the second processing agent from the surface of the substrate.

### (Third Modification)

For example, the first processing agent may be more likely to remain in recesses on the surface of a substrate than the second processing agent. In this case, SCFP may be performed in step B1, and NP may be performed in step B2. In this modification as well, effects similar to those of the above-described embodiments are obtained. Further, according to this modification, the purge effect in step B1 may be higher than the purge effect in step B2, such that, even in a case where the first processing agent is more likely to remain in recesses on the surface of the substrate than the second processing agent, it is possible to sufficiently remove residual components of both the first processing agent and the second processing agent from the surface of the substrate.

In addition, NP may be performed by using the lines I, J, and K in which no reservoir is installed, or may be performed by using a line in which a reservoir is installed. In the latter case, NP may be performed by setting both an upstream-side valve and a downstream-side valve of the reservoir to an open state. The line used in NP is selected so as not to affect SCFP performed in step B1.

### (Fourth Modification)

For example, the second processing agent may be more likely to remain in recesses on the surface of the substrate than the first processing agent. In this case, NP may be performed in step B1, and SCFP may be performed in step B2. In this modification as well, effects similar to those of the above-described embodiments are obtained. Further, according to this modification, the purge effect in step B2 may be higher than the purge effect in step B1, such that, even in a case where the second processing agent is more likely to remain in recesses on the surface of the substrate than the first processing agent, it is possible to sufficiently remove residual components of both the first processing agent and the second processing agent from the surface of the substrate.

In addition, NP may be performed by using the lines I, J, and K in which no reservoir is installed, or may be performed by using a line in which a reservoir is installed. In the latter case, NP may be performed by setting both an upstream-side valve and a downstream-side valve of the reservoir to an open state. The line used in NP is selected so as not to affect SCFP performed in step B2.

### (Fifth Modification)

After SCFP is performed, the purge gas may be continuously supplied into the process chamber. That is, after performing a purge accompanied by intermittent flush supply of the purge gas in short cycles, a purge may be performed continuously without flush supply of the purge gas. In other words, NP may be performed after SCFP is performed. In this case, after performing a purge accompanied by changes in the supply flow rate of the purge gas into the process chamber and changes in the internal pressure of the process chamber, a purge substantially without such changes is continuously performed. In this modification as well, effects similar to those of the above-described embodiments are obtained. Further, according to this modification, even in a case where processing agents, reaction by-products, and others remain in the process chamber for some reasons after SCFP, it is possible to effectively remove such remaining substances from the process chamber, thereby further enhancing the purge effect when purging the interior of the process chamber.

In addition, since FIG. 4 illustrates an example in which the purge gas is continuously supplied into the process chamber from the lines I, J, and K, FIG. 4 may be regarded as illustrating an example in which the purge gas is continuously supplied into the process chamber after SCFP is performed. When the purge gas is continuously supplied into the process chamber after SCFP is performed, it is possible to further enhance the purge effect by setting the supply flow rate of the purge gas from the lines I, J, and K to be greater than that during SCFP.

Alternatively, after SCFP is performed, the purge gas may be continuously supplied into the process chamber from a line in which a reservoir is installed. In this case, the purge gas may be continuously supplied into the process chamber by setting both an upstream-side valve and a downstream-side valve of the reservoir to an open state. In addition, the line provided with a reservoir used in this case is selected so as not to affect the subsequent SCFP.

### (Sixth Modification)

The purge gas may be continuously supplied into the process chamber after each of intermittent supplies of the purge gas in SCFP. That is, a purge without flush supply of the purge gas may be performed continuously after each intermittent flush supply of the purge gas in short cycles. In other words, NP may be performed after each FP that is performed a plurality of times in SCFP. In this case, each time a purge accompanied by changes in the supply flow rate of the purge gas into the process chamber and changes in the internal pressure of the process chamber is performed once, a purge substantially without such changes is continuously performed. In this modification as well, effects similar to those of the above-described embodiments are obtained. Further, according to this modification, even in a case where processing agents, reaction by-products, and others remain in the process chamber for some reasons after each of intermittent supplies of the purge gas in SCFP, it is possible to effectively remove such remaining substances from the process chamber, thereby further enhancing the purge effect when purging the interior of the process chamber.

In addition, since FIG. 4 illustrates an example in which the purge gas is continuously supplied into the process chamber from the lines I, J, and K, FIG. 4 may be regarded as illustrating an example in which the purge gas is continuously supplied into the process chamber after each of intermittent supplies of the purge gas in SCFP. When the purge gas is continuously supplied into the process chamber after each FP in SCFP, it is possible to further enhance the purge effect by setting the supply flow rate of the purge gas from the lines I, J, and K to be greater than that during FP.

Alternatively, after each of intermittent supplies of the purge gas in SCFP, the purge gas may be continuously supplied into the process chamber from a line in which a reservoir is installed. In this case, the purge gas may be continuously supplied into the process chamber by setting both an upstream-side valve and a downstream-side valve of the reservoir to an open state. In addition, the line provided with the reservoir used in this case is selected so as not to affect the subsequent flush supply of the purge gas.

### (Seventh Modification)

The residual amount (residual concentration, extent of residue, or residual tendency) of a purge target substance (such as processing agents and reaction by-products) may be different between some of a plurality of locations and other ones of the plurality of locations in the process chamber, for example, between some of a plurality of locations and other ones of the plurality of locations in a substrate arrangement region in which a plurality of substrates are arranged in the process chamber.

In such a case, at least one selected from the group of the number of times the purge gas is supplied, the supply cycle of the purge gas, the total supply amount of the purge gas, the maximum supply flow rate of the purge gas, the charging pressure of the purge gas being charged into the reservoir for supply, the charging time of the purge gas being charged into the reservoir for supply, the volume of the reservoir charged with the purge gas for supply, the charging amount of the purge gas being charged into the reservoir for supply, and the supply amount of the purge gas for each supply be adjusted to be different between some of a plurality of locations and other ones of the plurality of locations in the process chamber, for example, between some of a plurality of locations and other ones of the plurality of locations in the substrate arrangement region.

For example, the purge target substance may be more likely to remain in some of a plurality of locations in the process chamber (hereinafter also simply referred to as some portions) than in other ones of the plurality of locations in the process chamber (hereinafter also simply referred to as other portions).

In this case, for example, the number of times the purge gas is supplied to some portions is set to be greater than the number of times the purge gas is supplied to other portions. For example, the number of times the purge gas is supplied to some portions is set to 10 to 20 times, and the number of times the purge gas is supplied to other portions is set to 2 to 9 times.

Further, for example, the supply cycle of the purge gas to some portions is set to be shorter than the supply cycle of the purge gas to other portions. For example, the supply cycle of the purge gas to some portions is set to 1 to 4 seconds, and the supply cycle of the purge gas to other portions is set to 5 to 10 seconds.

Further, for example, the total supply amount of the purge gas to some portions is set to be greater than the total supply amount of the purge gas to other portions. For example, the total supply amount of the purge gas to some portions is set to 5 to 20 L, and the total supply amount of the purge gas to other portions is set to 1 to 4 L.

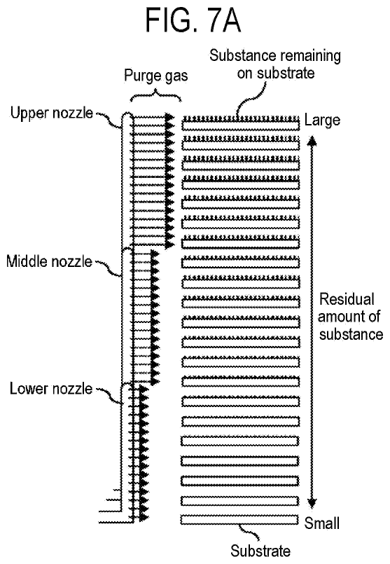

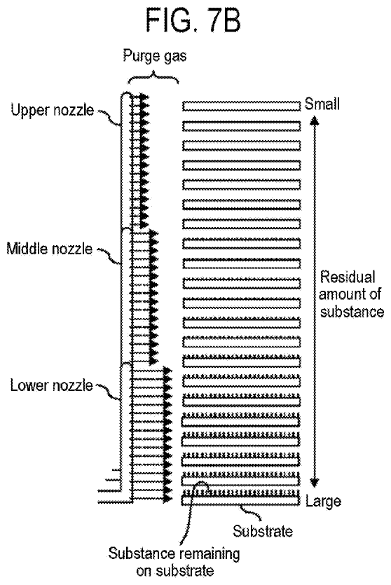

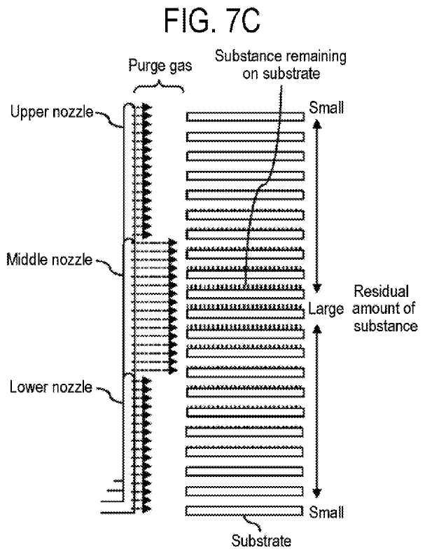

Further, for example, as illustrated in FIGS. 7A to 7C, the maximum supply flow rate of the purge gas to some portions is set to be greater than the maximum supply flow rate of the purge gas to other portions. For example, the maximum supply flow rate of the purge gas to some portions is set to 20 to 50 slm, and the maximum supply flow rate of the purge gas to other portions is set to 1 to 19 slm. In FIGS. 7A to 7C, lengths of arrows extending from respective nozzles (an upper nozzle, a middle nozzle, and a lower nozzle) indicate relative magnitudes of the amount or flow rate of the purge gas. For example, FIG. 7A illustrates an example in which the flow rate (amount) of the purge gas ejected from the upper nozzle is set to be greater than the flow rate (amount) of the purge gas ejected from the other nozzles, such that the flow rate (amount) of the purge gas ejected toward upper substrates, where the residual substance is greatest, is maximized. Further, for example, FIG. 7B illustrates an example in which the flow rate (amount) of the purge gas ejected from the lower nozzle is set to be greater than the flow rate (amount) of the purge gas ejected from the other nozzles, such that the flow rate (amount) of the purge gas ejected toward lower substrates, where the residual substance is greatest, is maximized. Further, for example, FIG. 7C illustrates an example in which the flow rate (amount) of the purge gas ejected from the middle nozzle is set to be greater than the flow rate (amount) of the purge gas ejected from the other nozzles, such that the flow rate (amount) of the purge gas ejected toward middle substrates, where the residual substance is greatest, is maximized. Such control illustrated in these drawings may also be performed by individually regulating diameters, that is, opening areas, of gas supply holes formed in long nozzles such as the nozzles 249a to 249c, so as to correspond to upper, middle, and lower regions of a space in which the substrates are arranged.

Further, for example, the charging pressure of the purge gas being charged into the reservoir for supply to some portions is set to be higher than the charging pressure of the purge gas being charged into the reservoir for supply to other portions. For example, the charging pressure of the purge gas being charged into the reservoir for supply to some portions is set to 20,000 to 80,000 Pa, and the charging pressure of the purge gas being charged into the reservoir for supply to other portions is set to 10,000 to 19,000 Pa. Further, for example, the charging time of the purge gas being charged into the reservoir for supply to some portions is set to be longer than the charging time of the purge gas being charged into the reservoir for supply to other portions. For example, the charging time of the purge gas being charged into the reservoir for supply to some portions is set to 6 to 10 seconds, and the charging time of the purge gas being charged into the reservoir for supply to other portions is set to 1 to 5 seconds. Further, for example, the volume of the reservoir charged with the purge gas for supply to some portions is set to be greater than the volume of the reservoir charged with the purge gas for supply to other portions. For example, the volume of the reservoir charged with the purge gas for supply to some portions is set to 3 to 4 L, and the volume of the reservoir charged with the purge gas for supply to other portions is set to 1 to 2 L. In such an example, the charging amount of the purge gas being charged into the reservoir for supply to some portions may be set to be greater than the charging amount of the purge gas being charged into the reservoir for supply to other portions. For example, the charging amount of the purge gas being charged into the reservoir for supply to some portions may be set to 2 to 3 L, and the charging amount of the purge gas being charged into the reservoir for supply to other portions may be set to 1 to 1.5 L. That is, in such an example, the supply amount of the purge gas for each supply to some portions may be set to be greater than the supply amount of the purge gas for each supply to other portions. In addition, FIGS. 7A to 7C may also be regarded as illustrating an example in which the supply amount of the purge gas for each supply to some portions is greater than the supply amount of the purge gas for each supply to other portions.

In addition, supply to some portions means supply toward or to some portions, and supply to other portions means supply toward or to other portions.

In this modification as well, effects similar to those of the above-described embodiments are obtained. Further, according to this modification, the purge effect for some portions may be higher than the purge effect for other portions by performing at least one of these regulations. Thereby, it is possible to sufficiently remove the purge target substance from both some portions and other portions, even in a case where the purge target substance is more likely to remain in some portions than in other portions.

### (Eighth Modification)

The processing agents (the first processing agent and the second processing agent) may be supplied intermittently a plurality of times in short cycles with a shifted timing by flush supply (continuous supply or rapid supply). In this modification as well, effects similar to those of the above-described embodiments are obtained. Further, according to this modification, the above-described effects obtained by flush supply of the processing agent are obtained more efficiently. In addition, in such a case, similarly to the purge gas, the processing agent (the first processing agent and the second processing agent) may be recharged into the respective reservoirs immediately after flush supply. In this case, this may be realized by replacing the purge gas in SCFP with the processing agents (the first processing agent and the second processing agent).

### Other Embodiments of Present Disclosure

The embodiments of the present disclosure are specifically described above. However, the present disclosure is not limited to the above-described embodiments, and various modifications may be made without departing from the gist of the present disclosure.

In the above-described embodiments, the example are described in which the purge gas is continuously supplied from each of the lines I, J, and K, but the present disclosure is not limited to the above-described embodiments. That is, as long as it is possible to prevent one processing agent from entering one nozzle when the one processing agent is supplied from another nozzle, the purge gas may not be continuously supplied from each of the lines I, J, and K. In this embodiment as well, effects similar to those in the above-described embodiments are obtained.

Further, in the above-described embodiments, the example is described in which both the first processing agent and the second processing agent are flush-supplied, but the present disclosure is not limited to the above-described embodiments. For example, one of the first processing agent and the second processing agent may be flush-supplied, and the other may be supplied without being charged into the reservoir. Further, for example, both the first processing agent and the second processing agent may be supplied without being charged into the reservoir. In these embodiments as well, effects similar to those of the above-described embodiments are obtained. Further, at least one of the reservoirs for the first processing agent and the second processing agent may be omitted, thereby simplifying the supply system accordingly.

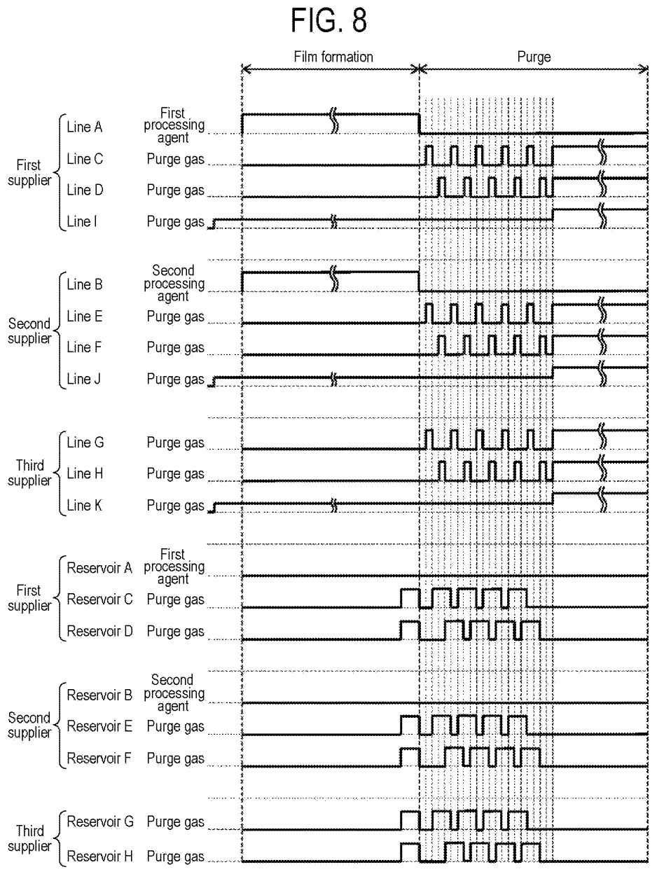

In addition, in the above-described embodiments, the example is described in which SCFP is performed in steps B1 and B2, but the present disclosure is not limited to the above-described embodiments. For example, SCFP may be performed at timings other than steps B1 and B2. Specifically, for example, as illustrated in FIG. 8, SCFP may be performed during a purge after film formation, that is, during an after-purge.

FIG. 8 illustrates an example in which, after performing a processing of forming a film on a substrate by a CVD method by simultaneously supplying the first processing agent and the second processing agent to the substrate, an after-purge is performed, and SCFP is performed during the after-purge.

Here, an example is illustrated in which the purge gas is flush-supplied simultaneously from a plurality of reservoirs via a plurality of suppliers (nozzles) during SCFP. Specifically, an example is illustrated in which simultaneously flush-supplying the purge gas from three of six reservoirs via three suppliers (nozzles) and simultaneously flush-supplying the purge gas from the remaining three of the six reservoirs via three suppliers (nozzles) are performed alternately. In this way, in SCFP, simultaneously flush-supplying the purge gas from the plurality of reservoirs via the plurality of nozzles may be intermittently performed a plurality of times in short cycles.

In this embodiment as well, effects similar to those in the above-described embodiments are obtained.

In addition, in this example, since the purge gas is flush-supplied simultaneously via the first supplier, the second supplier, and the third supplier, the first processing agent remaining in the first supplier and the second processing agent remaining in the second supplier may be simultaneously removed by being pushed out into the process chamber, thereby enabling SCFP to be performed efficiently. Further, at this time, the simultaneous flush supply of the purge gas via the third supplier may further enhance prevention of intrusion of the first and second processing agents, which were pushed out into the process chamber, into the third supplier.

In a case where the purge gas is first flush-supplied via the third supplier, and then the purge gas is flush-supplied via the first supplier and the second supplier, the first processing agent remaining in the first supplier and the second processing agent remaining in the second supplier would be pushed out into the process chamber after removal of the first and second processing agents from the process chamber, which may result in a reduction in purge efficiency.

Therefore, the purge gas may be flush-supplied first via the first supplier and the second supplier and then flush-supplied via the third supplier, or alternatively, simultaneously flush-supplied via the first supplier, the second supplier, and the third supplier. FIG. 8 illustrates an example of the latter. Thereby, it is possible to perform SCFP efficiently through the above-described action.

In addition, since FIG. 8 illustrates an example in which the purge gas is continuously supplied into the process chamber from the lines I, J, and K, FIG. 8 may be regarded as illustrating an example in which the purge gas is continuously supplied into the process chamber after SCFP is performed. Further, FIG. 8 illustrates an example in which, when the purge gas is continuously supplied into the process chamber after SCFP is performed, the supply flow rate of the purge gas from the lines I, J, and K is set to be greater than that during SCFP. Further, FIG. 8 illustrates an example in which the purge gas is continuously supplied into the process chamber from a line in which a reservoir is installed by opening an upstream-side valve and a downstream-side valve of the reservoir after SCFP is performed. According to this embodiment, effects similar to those of the fifth modification are also obtained.

Further, since FIG. 8 illustrates an example in which the purge gas is continuously supplied into the process chamber from the lines I, J, and K, FIG. 8 may be regarded as illustrating an example in which the purge gas is continuously supplied into the process chamber after each of intermittent supplies of the purge gas in SCFP, that is, after each FP. When the purge gas is continuously supplied into the process chamber after each FP in SCFP, the supply flow rate of the purge gas from the lines I, J, and K may be set to be greater than that during FP. Further, the purge gas may be continuously supplied into the process chamber from a line in which a reservoir is installed by opening an upstream-side valve and a downstream-side valve of the reservoir after each FP in SCFP. According to this embodiment, effects similar to those of the sixth modification are also obtained.

Further, in the above-described embodiments, an example are described in which SCFP is performed in steps B1 and B2, but the present disclosure is not limited to the above-described embodiments. For example, in addition to performing SCFP during the above-described after-purge, that is, after processing the substrate, SCFP may be performed before processing the substrate. That is, SCFP may be performed in at least one selected from the group of before and after processing the substrate. Further, SCFP may be performed in the process chamber in a state where no substrate is present in the process chamber, for example, during an idle period of the processing apparatus. Further, SCFP may be performed in at least one selected from the group of before and after gas cleaning in the process chamber. In this case as well, effects similar to those of the above-described embodiments are obtained.

Further, in the above-described embodiments, the example in which an SiN film is formed on the substrate are described, but, in addition to the SiN film, for example, a semiconductor element-containing film, that is, a silicon (Si)-containing film or a germanium (Ge)-containing film, such as a silicon carbon nitride film (SiCN film), a silicon oxycarbon nitride film (SiOCN film), a silicon oxycarbide film (SiOC film), a silicon oxide film (SiO film), a silicon borocarbon nitride film (SiBCN film), a silicon boron nitride film (SiBN film), a silicon film (Si film), a silicon germanium film (SiGe film), or a germanium film (Ge film), may be formed. In addition, for example, a metal element-containing film, such as an aluminum oxide film (AlO film), a hafnium oxide film (HfO film), a zirconium oxide film (ZrO film), a titanium oxide film (TiO film), a molybdenum oxide film (MoO film), an aluminum nitride film (AlN film), a hafnium nitride film (HfN film), a zirconium nitride film (ZrN film), a titanium nitride film (TiN film), a molybdenum nitride film (MoN film), or a tungsten film (W film), may be formed. In this case as well, effects similar to those of the above-described embodiments are obtained.

Further, in the above-described embodiments, the example is described in which an Si-containing substance is used as the first processing agent (precursor), but, for example, a Ge-containing substance (Ge-containing gas) such as monogermane (GeH₄) may be used, and for example, a metal-containing substance (metal-containing gas) such as trimethylaluminum (Al(CH₃)₃), hafnium tetrachloride (HfCl₄), zirconium tetrachloride (ZrCl₄), or titanium tetrachloride (TiCl₄) may be used. Further, in the above-described embodiments, the example in which a nitriding agent is used as the second processing agent (reactant) is described, but, for example, an oxygen (O)-containing substance, that is, an oxidizing agent (oxidizing gas), such as oxygen (O₂), ozone (O₃), water vapor (H₂O), hydrogen peroxide (H₂O₂), nitrous oxide (N₂O), nitric oxide (NO), nitrogen dioxide (NO₂), carbon monoxide (CO), or carbon dioxide (CO₂) may be used. Further, when forming the above-described ternary film or quaternary film on a substrate, for example, a substance (gas) serving as a N source, C source, or B source, such as triethylamine ((C₂H₅)₃N), monomethylhydrazine ((CH₃)HN₂H₂), propylene (C₃H₆), or boron trichloride (BCl₃), may further be used as the second processing agent (reactant). In this case as well, effects similar to those of the above-described embodiments are obtained.

In the above-described embodiments, the example in which the film formation processing is performed as a substrate process is described, but SCFP may also be performed when various types of processing such as oxidation processing, nitridation processing, diffusion processing, annealing processing, thermal processing, plasma processing, and etching processing are performed. In those cases, SCFP may be performed before, during, or after various types of processing. In this case as well, effects similar to those of the above-described embodiments are obtained.

In the above-described embodiments, the example is described in which the number of reservoirs for FP is six, but the number of reservoirs for FP may be set to 5 or less, or 7 or more. For example, the number of reservoirs for FP may be set to 2 to 30, specifically 3 to 20, and more specifically 4 to 10. As the number of reservoirs for FP increases, control to perform SCFP may be simplified. Conversely, as the number of reservoirs for FP decreases, an apparatus cost may be reduced. In addition, to perform SCFP for each line configured to supply the processing agent, two or more FP reservoirs may be installed for each line configured to supply one processing agent. The above-described embodiments illustrates the example in which two FP reservoirs are installed for each line configured to supply one processing agent.

In the above-described embodiments, the example is described in which the tanks 260a to 260h are used as the reservoirs A to H, but the gas supply pipes 232a to 232h between the valves 243a to 243h and the valves 247a to 247h may be used as the reservoirs A to H without installing the tanks 260a to 260h. That is, a substance (the first processing agent, the second processing agent, or the purge gas) temporarily charged in an interior of a gas supply pipe sandwiched between two valves may be flush-supplied. In this case as well, effects similar to those of the above-described embodiments are obtained.

Recipes used in each process may be prepared individually according to the processing contents and may be recorded and stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible for the processing apparatus to perform various processes with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the processing apparatus. Once the recipes are modified, the modified recipes may be installed in the processing apparatus via a telecommunication line or a recording medium storing the recipes. In addition, the existing recipes already installed in the existing processing apparatus may be directly modified by operating the input/output device 122 of the processing apparatus.

An example in which a process is performed by using a batch-type processing apparatus capable of processing a plurality of substrates at a time is described in the above-described embodiments. The present disclosure is not limited to the above-described embodiments, but may be applied, for example, to a case where a process is performed by using a single-wafer type processing apparatus capable of processing a single substrate or several substrates at a time. In addition, an example in which a process is performed by using a processing apparatus provided with a hot-wall-type process furnace is described in the above-described embodiments. The present disclosure is not limited to the above-described embodiments, but may be applied to a case where a process is performed by using a processing apparatus provided with a cold-wall-type process furnace.

In addition, in the above-described embodiments, an example is described in which the above-described processing sequence is performed in the same process chamber of the same processing apparatus (in-situ). The present disclosure is not limited to the above-described embodiments, and for example, one step and another step of the above-described processing sequences may be performed respectively in different process chambers of different processing apparatuses (ex-situ).

Even in a case where such a processing apparatus (processing system) is used, each processing may be performed under the same processing procedures and processing conditions as those in the above-described embodiments and modifications, and effects similar to those in the above-described embodiments and modifications may be obtained.

The above-described embodiments and modifications may be used in appropriate combinations. Processing procedures and processing conditions in such cases may be, for example, the same as the processing procedures and processing conditions of the above-described embodiments and modifications.

According to the present disclosure, it is possible to enhance the purge effect and the purge efficiency when purging the interior of a process chamber.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
(a) charging a purge gas into each of a plurality of reservoirs; and
(b) sequentially supplying the purge gas from each of the plurality of reservoirs charged with the purge gas into a process chamber a predetermined number of times with an intermittent period therebetween,
wherein (b) includes setting the intermittent period to be equal to or less than a charging time of the purge gas being charged into each of the plurality of reservoirs, or setting the intermittent period to be less than the charging time of the purge gas being charged into each of the plurality of reservoirs.

2. The processing method of claim 1, further comprising:
(c) supplying a processing agent to a substrate in the process chamber,
wherein a cycle including (c) and (b) is performed a predetermined number of times.

3. The processing method of claim 1, further comprising:
(c1) supplying a first processing agent to a substrate in the process chamber; and
(c2) supplying a second processing agent to the substrate in the process chamber,
wherein a cycle including (c1), (c2), and (b) is performed a predetermined number of times.

4. The processing method of claim 3, wherein a cycle in which (c1), (b), (c2), and (b) are performed in this order is performed a predetermined number of times.

5. The processing method of claim 4, wherein the number of times the purge gas is supplied in (b) performed after (c1) and before (c2) is set to be different from the number of times the purge gas is supplied in (b) performed after (c2).

6. The processing method of claim 4, wherein a supply cycle of the purge gas in (b) performed after (c1) and before (c2) is set to be different from a supply cycle of the purge gas in (b) performed after (c2).

7. The processing method of claim 4, wherein a total supply amount of the purge gas in (b) performed after (c1) and before (c2) is set to be different from a total supply amount of the purge gas in (b) performed after (c2).

8. The processing method of claim 4, wherein a maximum supply flow rate of the purge gas in (b) performed after (c1) and before (c2) is set to be different from a maximum supply flow rate of the purge gas in (b) performed after (c2).

9. The processing method of claim 4, wherein a charging pressure of the purge gas being charged into each of the plurality of reservoirs for supply in (b) performed after (c1) and before (c2) is set to be different from a charging pressure of the purge gas being charged into each of the plurality of reservoirs for supply in (b) performed after (c2).

10. The processing method of claim 4, wherein a charging time of the purge gas being charged into each of the plurality of reservoirs for supply in (b) performed after (c1) and before (c2) is set to be different from a charging time of the purge gas being charged into each of the plurality of reservoirs for supply in (b) performed after (c2).

11. The processing method of claim 4, wherein a volume of each of the plurality of reservoirs charged with the purge gas for supply in (b) performed after (c1) and before (c2) is set to be different from a volume of each of the plurality of reservoirs charged with the purge gas for supply in (b) performed after (c2).

12. The processing method of claim 4, wherein a charging amount of the purge gas being charged into each of the plurality of reservoirs for supply in (b) performed after (c1) and before (c2) is set to be different from a charging amount of the purge gas being charged into each of the plurality of reservoirs for supply in (b) performed after (c2).

13. The processing method of claim 4, wherein a supply amount of the purge gas for each supply in (b) performed after (c1) and before (c2) is set to be different from a supply amount of the purge gas for each supply in (b) performed after (c2).

14. The processing method of claim 4, wherein a maximum pressure change amount in the process chamber in (b) performed after (c1) and before (c2) is set to be different from a maximum pressure change amount in the process chamber in (b) performed after (c2).

15. The processing method of claim 3, further comprising:
(d) supplying the purge gas into the process chamber without charging the purge gas into each of the plurality of reservoirs,
wherein a cycle in which (c1), (b), (c2), and (d) are performed in this order is performed a predetermined number of times, or a cycle in which (c1), (d), (c2), and (b) are performed in this order is performed a predetermined number of times.

16. The processing method of claim 1, wherein, in (b), the purge gas is continuously supplied into the process chamber after intermittent supplies of the purge gas.

17. The processing method of claim 1, wherein, in (b), the purge gas is continuously supplied into the process chamber after each of intermittent supplies of the purge gas.

18. The processing method of claim 1, wherein (b) is performed for a plurality of locations in the process chamber, and
wherein at least one selected from the group of the number of times the purge gas is supplied, a supply cycle of the purge gas, a total supply amount of the purge gas, a maximum supply flow rate of the purge gas, a charging pressure of the purge gas being charged into each of the plurality of reservoirs for supply of the purge gas, a charging time of the purge gas being charged into each of the plurality of reservoirs for supply of the purge gas, a volume of each of the plurality of reservoirs charged with the purge gas for supply, a charging amount of the purge gas being charged into each of the plurality of reservoirs for supply of the purge gas, and a supply amount of the purge gas for each supply is set to be different between a portion of the plurality of locations and another portion of the plurality of locations.

19. The processing method of claim 18, wherein the plurality of locations include a plurality of locations in a region in which a plurality of substrates are arranged in the process chamber.

20. A method of manufacturing a semiconductor device, comprising the processing method of claim 1.

21. A processing apparatus comprising:
a process chamber;
a purge gas supply system configured to supply a purge gas into the process chamber;
a plurality of reservoirs configured to be capable of being charged with the purge gas; and
a controller configured to be capable of controlling implementation of a process including: (a) charging the purge gas into each of the plurality of reservoirs; and (b) sequentially supplying the purge gas from each of the plurality of reservoirs charged with the purge gas into the process chamber a predetermined number of times with an intermittent period therebetween, wherein (b) includes setting the intermittent period to be equal to or less than a charging time of the purge gas being charged into each of the plurality of reservoirs, or setting the intermittent period to be less than the charging time of the purge gas being charged into each of the plurality of reservoirs.

22. A non-transitory computer-readable recording medium storing a program that causes, by a computer, a processing apparatus to perform a process comprising:
(a) charging a purge gas into each of a plurality of reservoirs; and
(b) sequentially supplying the purge gas from each of the plurality of reservoirs charged with the purge gas into a process chamber a predetermined number of times with an intermittent period therebetween,
wherein (b) includes setting the intermittent period to be equal to or less than a charging time of the purge gas being charged into each of the plurality of reservoirs, or setting the intermittent period to be less than the charging time of the purge gas being charged into each of the plurality of reservoirs.
